(19) United States
(12) Patent Application Publication
(10) Pub. No.: US 2025/0107366 A1
(43) Pub. Date: Mar. 27, 2025

(54) DISPLAY PANEL

(71) Applicant: Samsung Display Co., Ltd., Yongin-si (KR)

(72) Inventors: SOOHONG CHEON, Yongin-si (KR); KYUNG-HO PARK, Yongin-si (KR)

(21) Appl. No.: 18/773,467

(22) Filed: Jul. 15, 2024

(30) Foreign Application Priority Data
Sep. 27, 2023 (KR) 10-2023-0130220

(51) Int. Cl. H10K 59/131; H10K 59/121; H10K 59/122; H10K 59/80

(52) U.S. Cl. CPC H10K 59/131; H10K 59/1213; H10K 59/1216; H10K 59/122; H10K 59/8792

(57) ABSTRACT

Provided is a display panel including a base layer, unit pixels comprising first, second, and third pixels, a first power line, a sensing line, a scan line, and first, second, and third data lines spaced apart along a first direction, extending along a second direction, and connected to the first, second, and third pixels, wherein the first, second, and third pixels comprise first, second, and third transistors above the base layer, a capacitor, and a light-emitting element, and wherein the capacitor of the first pixel is spaced apart from the capacitor of the second pixel along the second direction, and the capacitors of the first pixel and the second pixel are spaced apart from the capacitor of the third pixel along the first direction.

### CROSS-REFERENCE TO RELATED APPLICATION

This application claims priority to, and the benefit of, Korean Patent Application No. 10-2023-0130220, filed on Sep. 27, 2023, the entire contents of which are hereby incorporated by reference.

### BACKGROUND

The present disclosure herein relates to a display panel including a circuit element with improved reliability.

Display panels include a plurality of pixels and a driving circuit (e.g., a scan-driving circuit and a data-driving circuit) configured to control the plurality of pixels. The plurality of pixels each include a display element and a pixel-driving circuit configured to control the display element. The pixel-driving circuit may include a plurality of organically connected transistors and at least one capacitor.

### SUMMARY

The present disclosure provides a display panel having improved display quality.

One or more embodiments of the present disclosure provides a display panel including a base layer, unit pixels including first, second, and third pixels above the base layer, arranged along a first direction and a second direction, which cross each other, and including first, second, and third transistors above the base layer, a capacitor, and a light-emitting element, a first power line extending along the first direction, a sensing line extending along the first direction, and spaced apart from the first power line along the second direction, a scan line extending along the first direction and spaced apart from the first power line along the second direction with the sensing line therebetween, and first, second, and third data lines spaced apart along the first direction, extending along the second direction, and respectively connected to the first, second, and third pixels, wherein the capacitor of the first pixel is spaced apart from the capacitor of the second pixel along the second direction, and wherein the capacitor of the first pixel and the capacitor of the second pixel are spaced apart from the capacitor of the third pixel along the first direction.

The capacitors may be between the sensing line and the scan line, wherein the sensing line overlaps an upper portion of the capacitors, and wherein the scan line overlaps a lower portion of the capacitors.

The first data line may be between the second data line and the third data line, wherein the capacitors are between the first data line and the third data line.

The capacitors may respectively include upper electrodes, and respectively include first, second, and third light-blocking patterns above the base layer as respective lower electrodes.

The display panel may further include a first capacitor pattern overlapping the first light-blocking pattern, a second capacitor pattern overlapping the second light-blocking pattern, and a third capacitor pattern overlapping the third light-blocking pattern respectively as the upper electrodes.

A portion of the first capacitor pattern not overlapping the first light-blocking

pattern may include an active pattern of the second transistor of the first pixel, wherein a portion of the second capacitor pattern not overlapping the second light-blocking pattern includes an active pattern of the second transistor of the second pixel, and wherein a portion of the third capacitor pattern not overlapping the third light-blocking pattern includes an active pattern of the second transistor of the third pixel.

The scan line may include a first pattern and a second pattern protruding along the second direction and spaced apart along the first direction, the first pattern overlapping the active pattern of the second transistor of the first pixel and the second transistor of the second pixel, and the second pattern overlapping the active pattern of the second transistor of the third pixel.

Portions of the first pattern and the second pattern overlapping the active patterns may include gates of the second transistors of the first, second, and third pixels.

The second capacitor pattern may include a (2-1)-th capacitor pattern and a (2-2)-th capacitor pattern spaced apart along the second direction, wherein the active pattern of the first transistor of the second pixel is between the (2-1)-th capacitor pattern and the (2-2)-th capacitor pattern.

The display panel may further include a gate pattern including a gate of the first transistor of the second pixel overlapping the active pattern of the first transistor of the second pixel, the gate pattern connecting the (2-1)-th capacitor pattern and the (2-2)-th capacitor pattern.

The display panel may further include a first insulating layer above the base layer, and covering the first, second, and third data lines and the first, second, and third light-blocking patterns, a second insulating layer above the first insulating layer, and covering the first, second, and third capacitor patterns, a third insulating layer above the second insulating layer, and covering the first power line, the sensing line, and the scan line, and a pixel-defining layer above the third insulating layer, and defining openings exposing at least a portion of first electrodes of the light-emitting elements.

Among the openings, an opening corresponding to the first electrode of the first pixel may be defined as a first pixel region, an opening corresponding to the first electrode of the second pixel is defined as a second pixel region, and an opening corresponding to the first electrode of the third pixel is defined as a third pixel region, wherein an area of the second pixel region is less than an area of the first pixel region, and is greater than an area of the third pixel region.

The second pixel region and the third pixel region may be spaced apart along the first direction, wherein the first pixel region is spaced apart from the second pixel region and the third pixel region in respective diagonal directions that are diagonal with respect to the first direction and the second direction.

The display panel may further include a second power line connected to a second electrode of the first, second, and third pixels, above the base layer, extending along the second direction, and spaced apart from the second data line along the first direction.

In one or more embodiments of the present disclosure, a display panel includes a base layer, first, second, and third pixels above the base layer and including first, second, and third transistors, a capacitor, and a light-emitting element, first, second, and third data lines spaced apart along a first direction, and extending along a second direction crossing the first direction, a first power line extending along the first direction, a sensing line extending along the first direction, a scan line extending along the first direction, a second power line extending along the second direction, and an initial line extending along the second direction, wherein the second power line, the second data line, the first data line, the capacitor of the first pixel, the capacitor of the second pixel, the initial line, the capacitor of the third pixel, and the third data line are sequentially arranged along the first direction.

The first power line may be spaced apart from the scan line along the second direction with the sensing line therebetween, wherein the capacitors of the first, second, and third pixels are between the sensing line and the scan line.

The capacitor of the first pixel may be spaced apart from the capacitor of the second pixel along the second direction, wherein the capacitor of the first pixel and the capacitor of the second pixel are spaced apart from the capacitor of the third pixel along the first direction.

The initial line may be between the capacitor of the third pixel and the capacitors of the first pixel and the second pixel.

The display panel may further include a first insulating layer above the base layer and covering the first, second, and third data lines, the second power line, and the initial line, a second insulating layer above the first insulating layer, and covering active patterns of the first, second, and third transistors, a third insulating layer above the second insulating layer, and covering the first power line, the sensing line, and the scan line, and a pixel-defining layer above the third insulating layer, and defining openings exposing at least a portion of first electrodes of the light-emitting elements defined therein.

The capacitors may include a lower electrode above the base layer and covered by the first insulating layer, and an upper electrode above the first insulating layer and covered by the second insulating layer.

### BRIEF DESCRIPTION OF THE FIGURES

The accompanying drawings are included to provide a further understanding of the present disclosure, and are incorporated in and constitute a part of this specification. The drawings illustrate embodiments of the present disclosure and, together with the description, serve to explain aspects of the present disclosure. In the drawings:

FIG. 1A is a perspective view of a display panel according to one or more embodiments of the present disclosure;

FIG. 1B is a perspective view of a curved display panel according to one or more embodiments of the present disclosure;

FIG. 2A is a cross-sectional view of a display panel according to one or more embodiments of the present disclosure;

FIG. 2B is a plan view of a display panel according to one or more embodiments of the present disclosure;

FIG. 3 is an equivalent circuit diagram of pixels according to one or more embodiments of the present disclosure;

FIG. 4 is a plan view enlarging a display region according to one or more embodiments of the present disclosure;

FIG. 5A is a plan view according to the stacking order of conductive patterns included in unit pixels according to one or more embodiments of the present disclosure;

FIG. 5B is a cross-sectional view of a display panel, taken along the line I-I′ of FIG. 5A; and

FIGS. 6A to 6G are plan views in which the stacking order of conductive patterns included in unit pixels according to one or more embodiments of the present disclosure is divided by layer.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure. The present disclosure covers all modifications, equivalents, and replacements within the idea and technical scope of the present disclosure. Further, each of the features of the various embodiments of the present disclosure may be combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

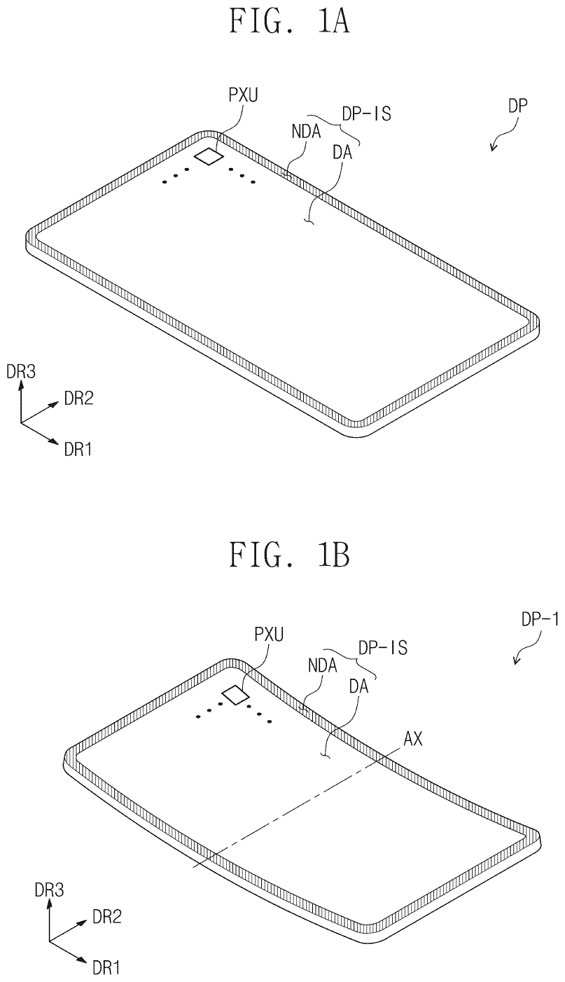

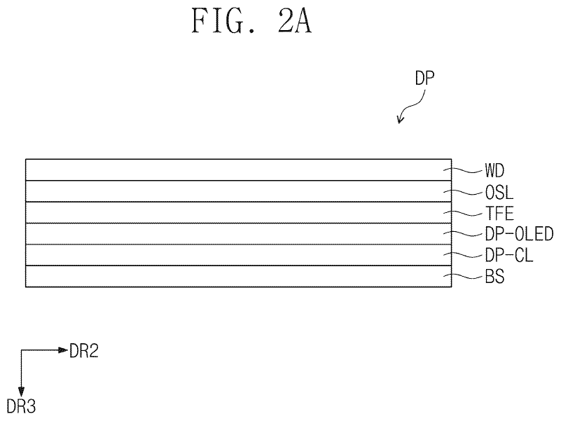

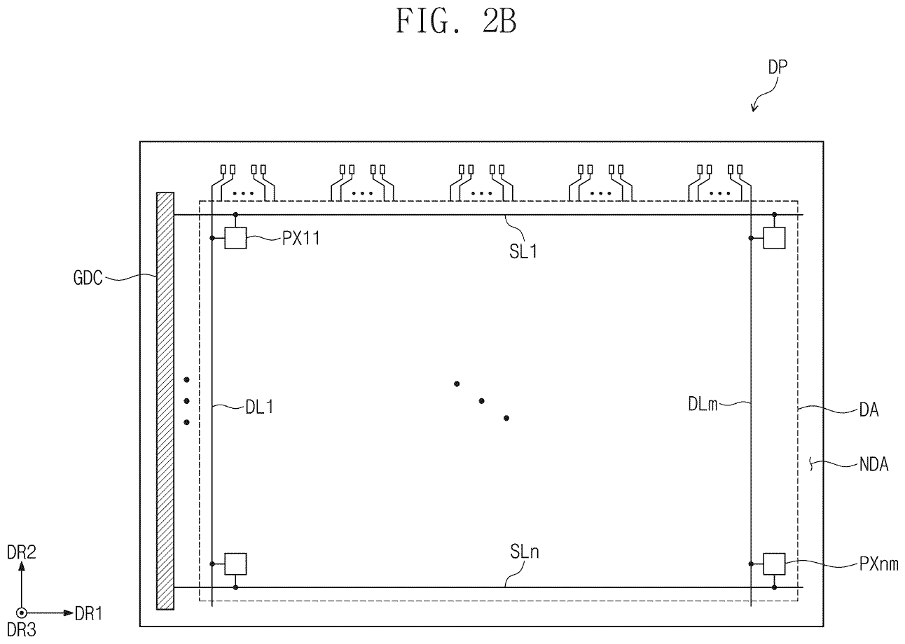

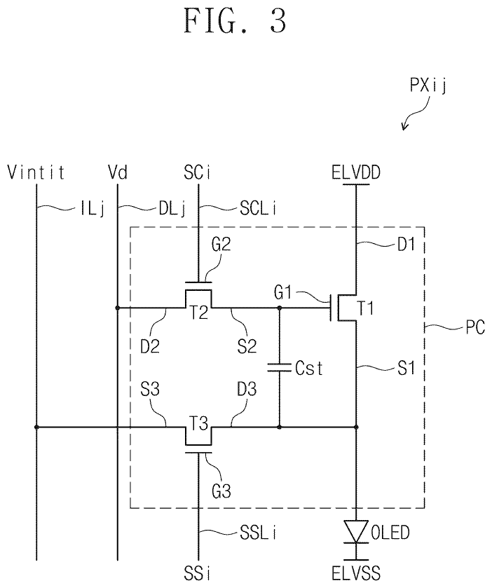

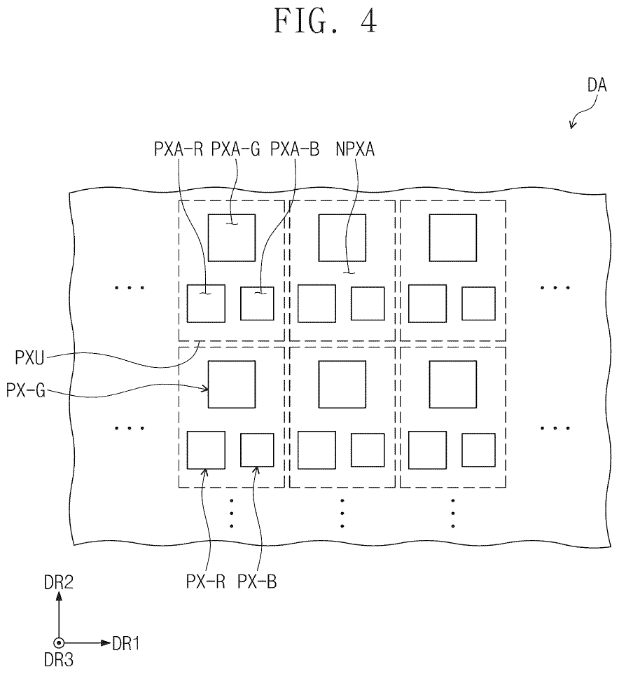

FIG. 1A is a perspective view of a display panel according to one or more embodiments of the present disclosure. FIG. 1B is a perspective view of a curved display panel according to one or more embodiments of the present disclosure. FIG. 2A is a cross-sectional view of a display panel according to one or more embodiments of the present disclosure. FIG. 2B is a plan view of a display panel according to one or more embodiments of the present disclosure. FIG. 3 is an equivalent circuit diagram of pixels according to one or more embodiments of the present disclosure. FIG. 4 is a 1 plan view enlarging a display region according to one or more embodiments of the present disclosure.

Display panels DP and DP-1 shown in FIGS. 1A and 1B are light-emitting display panels, and may be any one among a liquid crystal display panel, an electrophoretic display panel, a microelectromechanical system (MEMS) display panel, an electrowetting display panel, an organic light-emitting display panel, an inorganic light-emitting display panel, or a quantum dot display panel. In addition, the display panels DP and DP-1 according to one or more embodiments of the present disclosure may include ultra-small light-emitting elements. For example, the display panels DP and DP-1 may include micro LED elements and/or nano LED elements, but are not particularly limited.

Referring to FIG. 1A, the display panel DP may display images through a display surface DP-IS. An upper surface of a member located on an uppermost side of the display panel DP may be defined as the display surface DP-IS. According to one or more embodiments of the present disclosure, an upper surface of the window panel WD shown in FIG. 2A may be provided the display surface DP-IS of the display panel DP.

The display surface DP-IS may be parallel to a plane defined by a first direction DR1 and a second direction DR2. A normal direction of the display surface DP-IS, that is, a thickness direction of the display panel DP, is indicated by a third direction DR3. A front surface (or an upper surface) and a rear surface (or a lower surface) of respective layers or units, which will be described below, are separated by the third direction DR3.

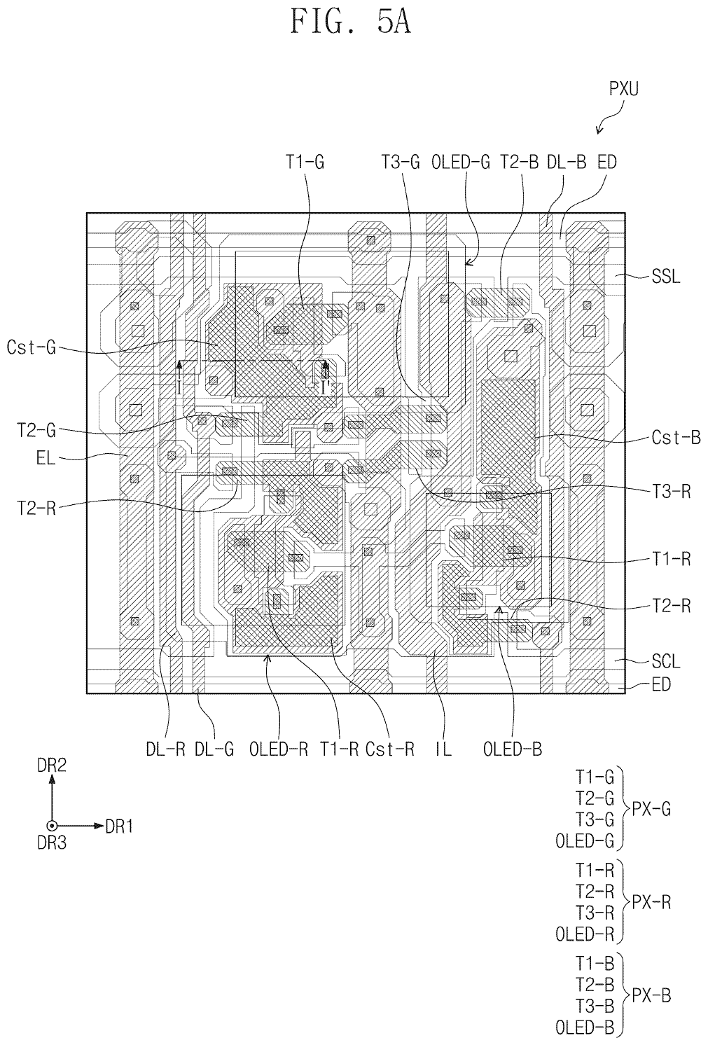

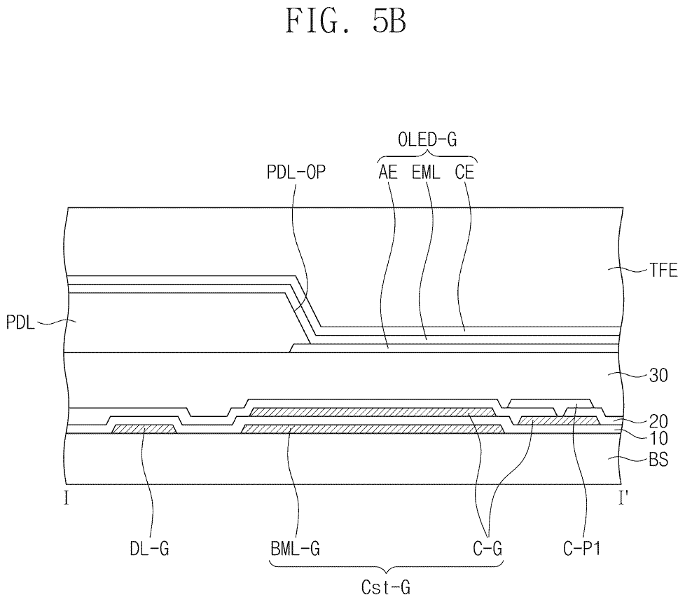

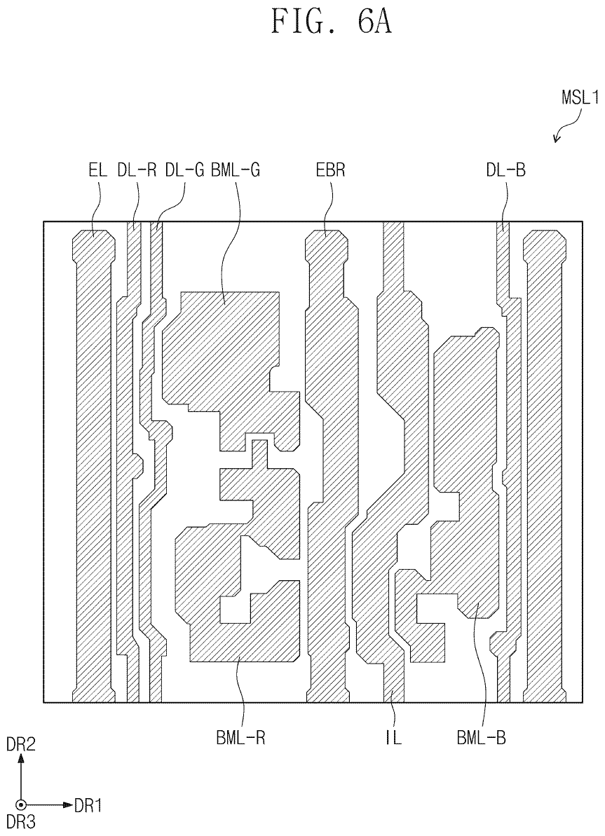

The display panel DP may include a display region DA and a non-display region NDA. An emission layer EML (see FIG. 5B) included in a pixel PXnm (see FIG. 2B) is located in the display region DA, and an emission layer EML (see FIG. 5B) included in the pixel PXnm is not located in the non-display region NDA. The non-display region NDA is defined along an edge of the display surface DP-IS. The non-display region NDA may surround the display region DA. In one or more embodiments of the present disclosure, the non-display region NDA may not be provided or may be located only on one side of the display region DA.

Referring to FIG. 1B, the display panel DP-1 according to one or more embodiments may be curved along the first direction DR1 with respect to a virtual axis

AX extending in the second direction DR2. However, the present disclosure is not limited thereto, and the axis may extend in the first direction DR1, or the display panel DP-1 may be curved with respect to a plurality of axes extending in different directions. According to one or more embodiments, the display panels DP and DP-1

may be a rollable display panel, a foldable display panel, or a slidable display panel. In this case, the display panels DP and DP-1 have flexible properties and may be folded or rolled when installed in a display device. Accordingly, the display panels DP and DP-1 may include a curved display surface or a three-dimensional display surface DP-IS. The three-dimensional display surface DP-IS may include a plurality of display regions indicating different directions.

A unit pixel PXU is shown to be located in an active region AA of FIGS. 1A and 1B. The unit pixel PXU may include at least two pixels for providing different light. For example, the unit pixel PXU may be a region in which pixels providing source light are located. The light-emitting area, shape, and arrangement of each of the pixels included in the unit pixel PXU are not limited to any one. For example, the light-emitting area of each of the pixels included in the unit pixel PXU may be different. In addition, each of the light-emitting regions may have a circular shape or a polygonal shape when viewed on a plane (e.g., in plan view).

Referring to FIGS. 2A and 2B, the display panel DP according to one or more embodiments of the present disclosure includes a base layer BS, a circuit element layer DP-CL located on the base layer BS, a display element layer DP-OLED, an encapsulation layer TFE, a light control layer OSL, and a window panel WD. The display panel DP may further include functional layers, such as an anti-reflection layer or a refractive index control layer. The circuit element layer DP-CL includes at least a plurality of insulating layers and a circuit element. Hereinafter, the insulating layers may include an organic layer and/or an inorganic layer.

The base layer BS may include a synthetic resin film. The synthetic resin layer may include a thermosetting resin. For example, the synthetic resin layer may include at least any one among an acrylic-based resin, a methacrylate-based resin, polyisoprene, a vinyl-based resin, an epoxy-based resin, a urethane-based resin, a cellulose-based resin, a siloxane-based resin, a polyamide-based resin, or a perylene-based resin. In addition, the base layer may include a glass substrate, a metal substrate, or an organic/inorganic composite material substrate.

The circuit element layer DP-CL may form an insulating layer, a semiconductor layer, and a conductive layer through processes, such as coating or deposition. Thereafter, the insulating layer, the semiconductor layer, and the conductive layer may be selectively patterned through photolithography and etching. Through the processes, a semiconductor pattern, a conductive pattern, a signal line, and the like are formed. Patterns located on the same layer are formed through the same process.

The circuit element layer DP-CL includes a driving circuit or a signal line constituting a pixel PX. The display element layer DP-OLED may include a light-emitting element OLED included in the pixel PX and a pixel-defining layer PDL (see FIG. 5B).

The encapsulation layer TFE may be located on the light-emitting element layer DP-OLED to protect the light-emitting element OLED. The encapsulation layer TFE may include inorganic layers, and an organic layer located between the inorganic layers. The inorganic layers may protect the light-emitting element OLED from moisture and oxygen, and the organic layer may protect the light-emitting element OLED from foreign substances, such as dust particles.

The light control layer OSL may include light control patterns that may alter the optical properties of source light generated from a light-emitting element. The light control patterns may include quantum dots, and may include color filter patterns that selectively transmit light subjected to passing through the light control patterns.

The window panel WD may be located above the display panel DP, and may transmit images provided from the display panel DP to the outside. The window panel WD may separate the display region DA and the non-display region NDA of the display surface DP-IS, as shown in FIG. 1A. A border between the display region DA and the non-display region NDA may be defined by a bezel pattern located below the window panel WD and absorbing light.

The window panel WD may include a base layer and functional layers located on the base layer. The functional layers may include a protection layer, an anti-fingerprint layer, and the like. The base layer of the window panel WD may be formed of glass, sapphire, or plastic.

FIG. 2B shows the planar arrangement relationship of signal lines SL1 to SLn and DL1 to DLm and pixels PX11 to PXnm included in the display panel DP. The signal lines SL1 to SLn and DL1 to DLm may include a plurality of scan lines SL1 to SLn and a plurality of data lines DL1 to DLm.

The pixels PX11 to PXnm may be located in the display region DA. The pixels PX11 to PXnm are each connected to a corresponding scan line among the plurality of scan lines SL1 to SLn and a corresponding data line among the plurality of data lines DL1 to DLm. The pixels PX11 to PXnm may each include a pixel-driving circuit and a light-emitting element. More various types of signal lines may be provided in the display panel DP according to the configuration of the pixel-driving circuit of the pixels PX11 to PXnm.

The gate-driving circuit GDC may be located in the non-display region NDA. The gate-driving circuit GDC may be integrated on the display panel DP through an oxide silicon gate (OSG) driver circuit process or an amorphous silicon gate (ASG) driver circuit process.

FIG. 3 shows a circuit diagram of one pixel PXij among the pixels PX11 to PXnm.

The pixel PXij may include a pixel circuit PC and a light-emitting element OLED. The pixel circuit PC may include a plurality of transistors T1, T2, and T3 and a capacitor Cst.

According to one or more embodiments of the present disclosure, any one pixel PXij may include dual capacitors spaced apart from each other, and connected through a conductive pattern. Descriptions thereof will be provided later.

The plurality of transistors T1, T2, and T3 may be formed through a low temperature polycrystalline silicon (LTPS) process or a low temperature polycrystalline oxide (LTPO) process. Each of the first to third transistors T1, T2, and T3 may include any one of a silicon semiconductor or an oxide semiconductor. In this case, the oxide semiconductor may include a crystalline or amorphous oxide semiconductor, and the silicon semiconductor may include amorphous silicon, polycrystalline silicon, or the like, but the present disclosure is not limited to any one embodiment.

Hereinafter, the first to third transistors T1, T2, and T3 are described as N-type, but are not limited thereto, and each of the first to third transistors T1, T2, and T3 may be a P-type transistor or an N-type transistor according to applied signals. In this case, a source and a drain of the P-type transistor may correspond to a drain and a source of the N-type transistor, respectively.

FIG. 3 shows the pixel PXij connected to an i-th scan line SCLi, an i-th sensing line SSLi, a j-th data line DLj, and a j-th initial line ILj as an example.

The pixel circuit PC may include a first transistor T1 (a driving transistor), a second transistor T2 (a switch transistor), a third transistor T3 (a sensing transistor), and a capacitor Cst. However, the pixel circuit PC may further include an additional transistor and/or an additional capacitor, and is not limited to any one embodiment. The light-emitting element OLED may be an organic light-emitting element or

an inorganic light-emitting element, which includes an anode (a first electrode) and a cathode (a second electrode). The anode of the light-emitting element OLED may receive a first voltage ELVDD through the first transistor T1, and the cathode of the light-emitting element OLED may receive a second voltage ELVSS. The light-emitting element OLED may receive the first voltage ELVDD and the second voltage ELVSS to emit light.

The first transistor T1 may include a drain D1 for receiving the first voltage ELVDD, a source S1 connected to the anode of the light-emitting element OLED, and a gate G1 connected to the capacitor Cst. The first transistor T1 may control a driving current flowing through the light-emitting element OLED from the first voltage ELVDD in response to voltage values stored in the capacitor Cst.

The second transistor T2 may include a drain D2 connected to the j-th data line DLj, a source S2 connected to the capacitor Cst, and a gate G2 for receiving the i-th first scan signal SCi. The second transistor T2 provides the data voltage Vd to the first transistor T1 in response to the i-th first scan signal SCi.

The third transistor T3 may include a source S3 connected to the j-th initial

line ILj, a drain D3 connected to the anode of the light-emitting element OLED, and a gate G3 receiving the i-th second scan signal SSi. The j-th initial line ILj may receive an initial voltage Vintit.

The capacitor Cst may store a voltage difference of various values according to input signals. For example, the capacitor Cst may store a voltage corresponding to a difference between a voltage transmitted from the second transistor T2 and the first voltage ELVDD.

As shown in FIG. 4, light formed in a first pixel PX-G may be provided to a first pixel region PXA-G, light formed in a second pixel PX-R may be provided to a second pixel region PXA-R, and light formed in a third pixel PX-B may be provided to a third pixel region PXA-B. The first to third pixel regions PXA-G, PXA-R, and PXA-B may correspond to openings PDL-OP defined in the pixel-defining layer PDL, which will be described in FIG. 5B.

A peripheral region NPXA is located between the first to third pixel regions PXA-G, PXA-R, and PXA-R. The peripheral region NPXA sets a border between the first to third pixel regions PXA-R, PXA-G, and PXA-B to reduce or prevent color mixing between the first to third pixel regions PXA-R, PXA-G, and PXA-B.

The first to third pixels PX-G, PX-R, and PX-B may each include a light-emitting element OLED (e.g., OLED-G in FIG. 5B), and the first to third pixels PX-G, PX-R, and PX-B may generate source light of the same color. However, the light-emitting areas of the first to third pixels PX-G, PX-R, and PX-B may be the same or different.

The source light generated from the light-emitting elements OLED of the first to third pixels PX-G, PX-R, and PX-B may be converted to any one among red, green, or blue through light control patterns included in the light control layer OSL described in FIG. 2A. The converted light may be emitted through the first pixel region PXA-G, the second pixel region PXA-R, and the third pixel region PXA-B.

Referring to FIG. 4, the second pixel region PXA-R and the third pixel region PXA-B are located in the same row, and the first pixel region PXA-G is located in a row that is different from that of the second pixel region PXA-R and the third pixel region PXA-B. For example, the second pixel region PXA-R and the third pixel region PXA-B may be arranged to be spaced apart along the first direction DR1, the first pixel region PXA-G may be arranged to be spaced apart from the second pixel region PXA-R and the third pixel region PXA-B in respective diagonal directions that are diagonal with respect to each of the first direction DR1 and the second direction DR2.

According to one or more embodiments, the first pixel region PXA-G may have a greater area than the second pixel region PXA-R, and may have a greater area than the third pixel region PXA-B.

The first pixel region PXA-G, the second pixel region PXA-R, and the third pixel region PXA-B having a square shape, but the arrangement form and area of the pixel regions are not limited thereto.

The arrangement structure of the first pixel region PXA-G, the second pixel region PXA-R, and the third pixel region PXA-B in the unit pixel PXU shown in FIG. 4 is presented merely as an example, and the present disclosure is not limited thereto. In one or more embodiments of the present disclosure, the first pixel region PXA-G, the second pixel region PXA-R, and the third pixel region PXA-B may be arranged along the first direction DR1, and located in the same row. In addition, the arrangement of the first pixel region PXA-G, the second pixel region PXA-R, and the third pixel region PXA-B of each of the unit pixels PXU is not necessarily the same.

FIG. 5A is a plan view according to the stacking order of conductive patterns included in unit pixels according to one or more embodiments of the present disclosure. FIG. 5B is a cross-sectional view taken along the line I-l′ of FIG. 5A. The stacked structure of the conductive patterns included in FIG. 5A may correspond to the components included in the pixel circuit PC and the light-emitting element OLED described in FIG. 3. Accordingly, the same/similar reference numerals are used for the same/similar components as/to the components described in FIG. 3. In FIG. 5A, the light control layer OSL and window panel WD described in FIG. 2A are not provided. Referring to FIG. 5A, the unit pixel PXU may include first to third pixels PX-G, PX-R, and PX-B. The first to third pixels PX-G, PX-R, and PX-B may each include the pixel circuit PC and the light-emitting element OLED described in FIG. 3.

For example, the first pixel PX-G may include a first light-emitting element OLED-G, first to third transistors T1-G, T2-G, and T3-G, and a first capacitor Cst-G, the second pixel PX-R may include a second light-emitting element OLED-R, first to third transistors T1-R, T2-R, and T3-R, and a second capacitor Cst-R, and the third pixel PX-B may include a third light-emitting element OLED-B, first to third transistors T1-B, T2-B, and T3-B, and a third capacitor Cst-B.

In FIG. 5A, for convenience of description, first electrodes AE (see FIG. 5B) included in each of the first to third pixels PX-G, PX-R, and PX-B are shown to replace light-emitting elements OLED-R, OLED-G, and OLED-B.

Source light generated from the first pixel PX-G may be provided to the first pixel region PXA-G. Source light generated from the second pixel PX-R may be provided to the second pixel region PXA-R. Source light generated in the third pixel PX-B may be provided to the third pixel region PXA-B.

The first to third pixels PX-G, PX-R, and PX-B each are connected to a first

power line ED, a second power line EL, an initial line IL, a scan line SCL, and a sensing line SSL. In addition, the first to third pixels PX-G, PX-R, and PX-B may be connected to corresponding data lines DL-G, DL-R, and DL-B. The first power line ED may provide the first voltage ELVDD (see FIG. 3), and the second power line EL may provide the second voltage ELVSS (see FIG. 3) lower than the first voltage ELVDD.

According to one or more embodiments, the data lines DL-G, DL-R, and DL-B, the initial line IL, and the second power line EL may be spaced apart along the first direction DR1, and may each extend along the second direction DR2. The first power line ED, the scan line SCL, and the sensing line SSL may be spaced apart along the second direction DR2, and may each extend along the first direction DR1.

According to one or more embodiments of the present disclosure, the capacitors Cst-G, Cst-R, and Cst-B included in the first to third pixels PX-G, PX-R, and PX-B may be spaced apart when viewed on a plane. The first capacitor Cst-G may be spaced apart from the second capacitor Cst-R along the second direction DR2. The first capacitor Cst-G and the second capacitor Cst-R may be spaced apart from the third capacitor Cst-B along the first direction DR1.

The capacitors Cst-G, Cst-R, and Cst-B may be located between the sensing line SSL and the scan line SCL when viewed on a plane. According to one or more embodiments of the present disclosure, when viewed on a plane, the sensing line SSL may be located on (e.g., may overlap) an upper portion of the capacitors Cst-G, Cst-R, and Cst-B, and the scan line SCL may be located on (e.g., may overlap) a lower portion of the capacitors Cst-G, Cst-R, and Cst-B.

According to one or more embodiments of the present disclosure, the first capacitor Cst-G included in the first pixel PX-G is spaced apart from the second capacitor Cst-R included in the second pixel PX-R along the second direction, and accordingly, even when the first pixel region PXA-G of the first pixel PX-G is biased toward the second power line EL, the area of the second capacitor Cst-R may be secured. Accordingly, the display panel DP having improved driving properties of the second pixel PX-R may be provided.

Referring to FIGS. 5A and 5B, the display panel DP according to one or more embodiments may include a base layer BS, insulating layers 10, 20, and 30 located on the base layer BS, a pixel-defining layer PDL having an opening PDL-OP defined therein, an encapsulation layer TFE, and a first light-emitting element OLED-G of the first pixel PX-G. The description of the first light-emitting element OLED-G may similarly apply to the second light-emitting element OLED-R included in the second pixel PX-R and the third light-emitting element OLED-B included in the third pixel PX-B.

The base layer BS may include a synthetic resin film. The synthetic resin layer may include a thermosetting resin. For example, the synthetic resin layer may include at least any one among an acrylic-based resin, a methacrylate-based resin, polyisoprene, a vinyl-based resin, an epoxy-based resin, a urethane-based resin, a cellulose-based resin, a siloxane-based resin, a polyamide-based resin, or a perylene-based resin. In addition, the base layer may include a glass substrate, a metal substrate, or an organic/inorganic composite material substrate.

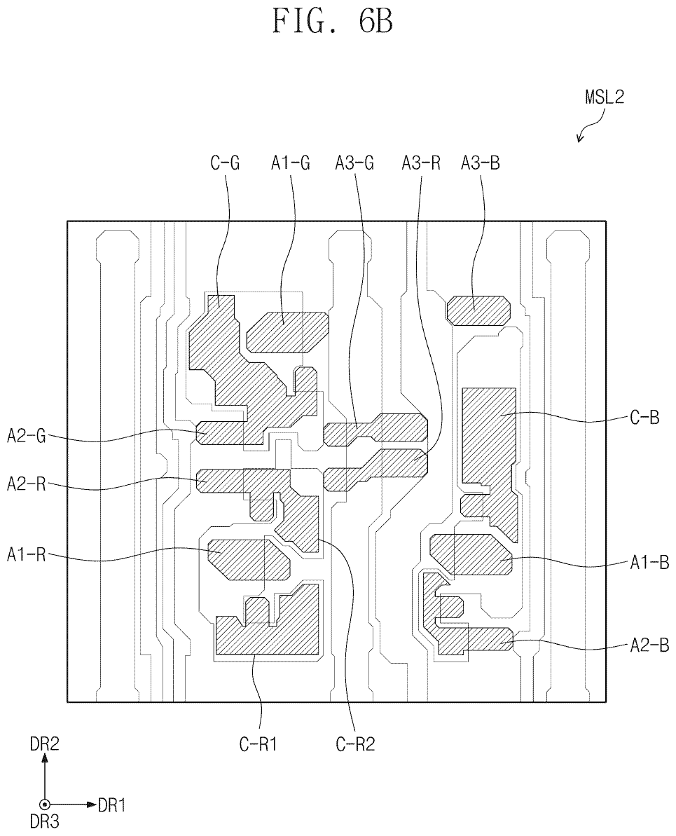

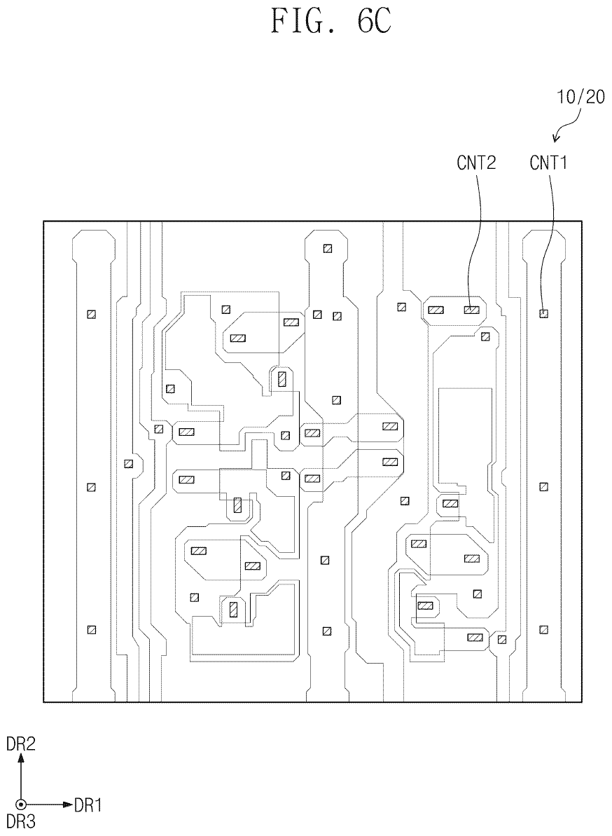

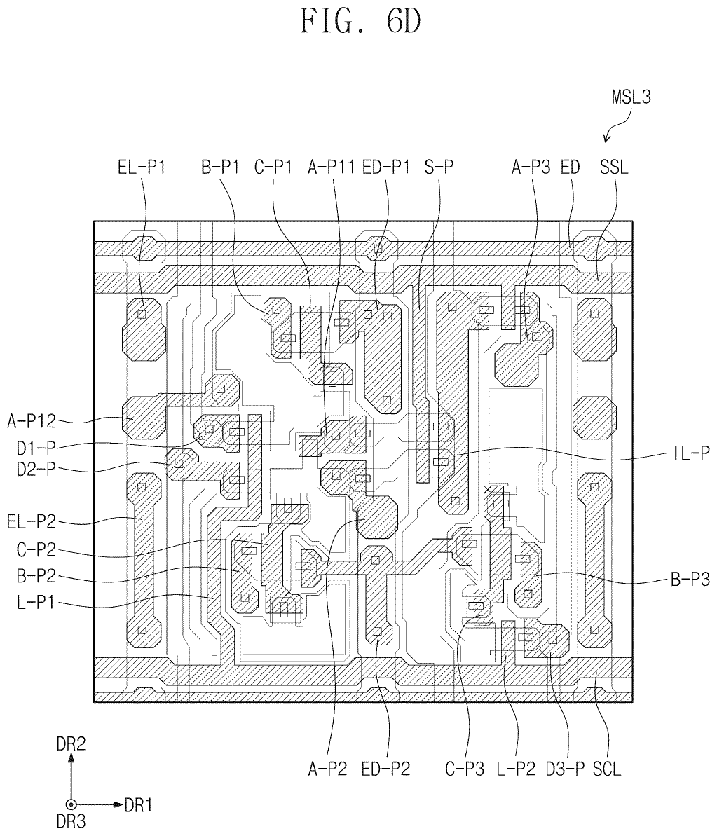

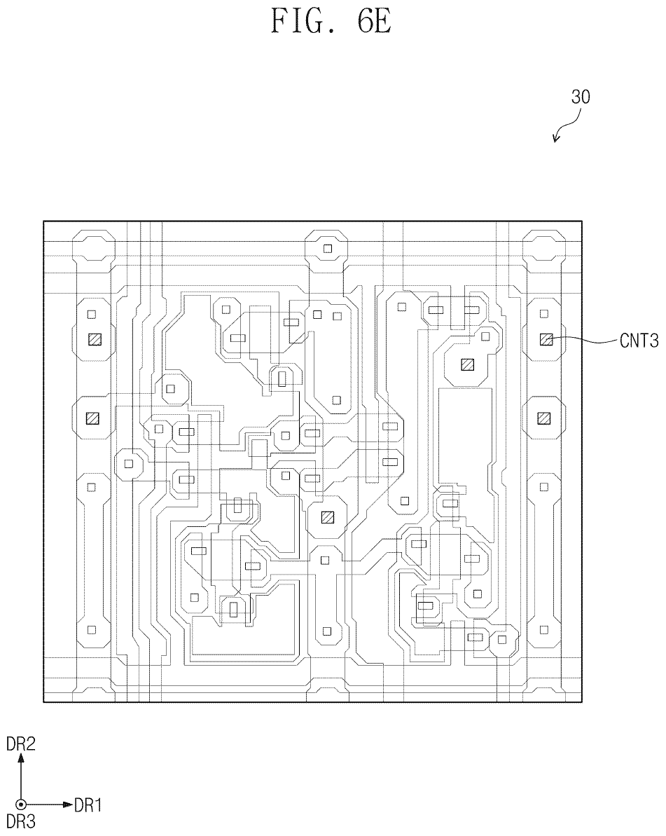

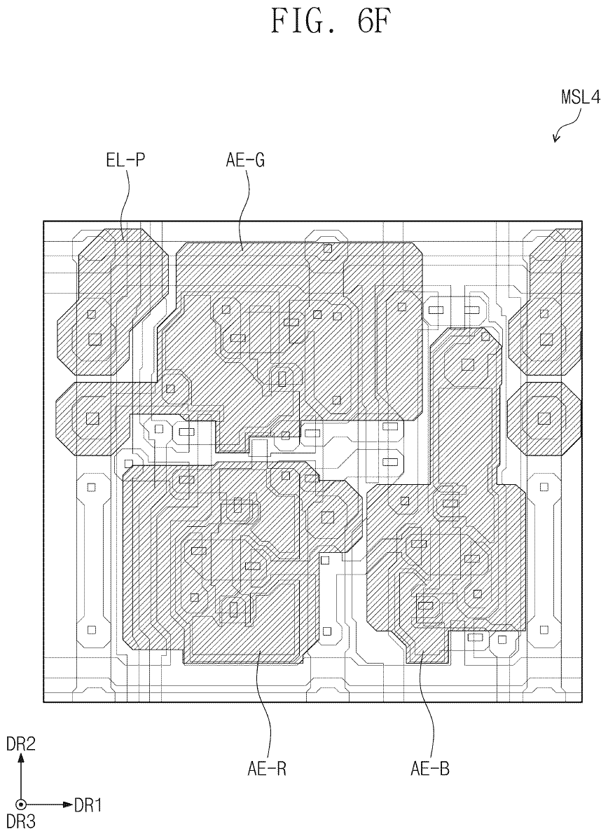

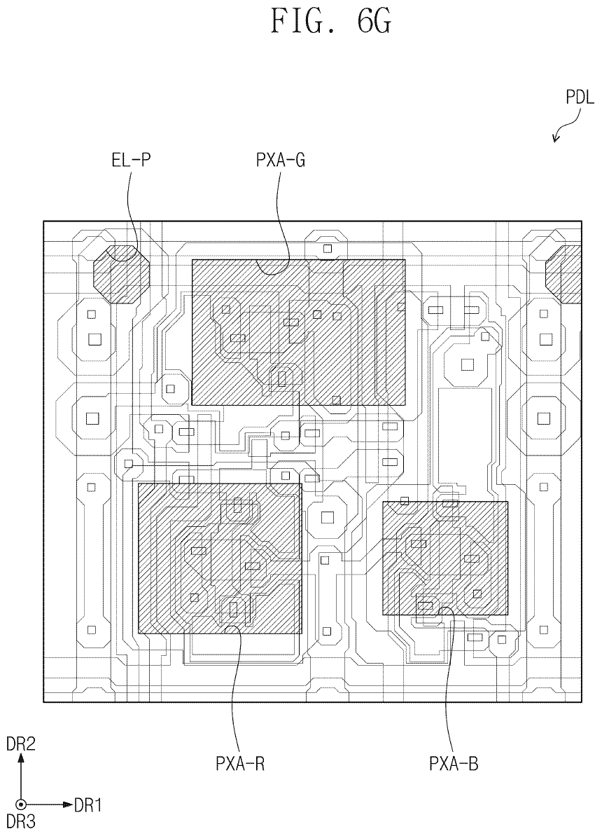

A first data line DL-G and a first light-blocking pattern BML-G may be located on the base layer BS. The first light-blocking pattern BML-G may be connected to the source of the first transistor T1-G included in the first pixel PX-G, and may receive signals applied to the source to form a sync structure at a lower portion of semiconductor patterns. The first light-blocking pattern BML-G may overlap a first active pattern A1-G (see FIG. 6B) to receive a bias voltage. The first light-blocking pattern BML-G may receive the first voltage ELVDD (see FIG. 3).

The first light-blocking pattern BML-G may block electrical potential resulting from polarization from affecting the first transistor T1-G. In addition, the first light-blocking pattern BML-G may block external light from reaching the first transistor T1-G. In one or more embodiments of the present disclosure, the first light-blocking pattern BML-G may be a floating electrode in a form isolated from other electrodes or lines.

The first data line DL-G may be spaced apart from the first light-blocking pattern BML-G. The first data line DL-G may be formed through the same process as the first light-blocking pattern BML-G, and may include the same material.

The first insulating layer 10 may be located on the base layer BS and may cover the first data line DL-G and the first light-blocking pattern BML-G.

The first capacitor pattern C-G of the first pixel PX-G may be located on the first insulating layer 10. The first capacitor pattern C-G may overlap the first light-blocking pattern BML-G to form the capacitor Cst-G of the first pixel PX-G.

The second insulating layer 20 may be located on the first insulating layer 10 and may cover the first capacitor pattern C-G. According to one or more embodiments, the first and second insulating layers 10 and 20 may include an inorganic layer. For example, the inorganic layer may include a silicon oxide layer and a silicon nitride layer. Each of these may be provided in plurality, and silicon oxide layers and silicon nitride layers may be alternately stacked.

A first gate pattern C-P1 may be located on the second insulating layer 20. The first gate pattern C-P1 may be connected to the first capacitor pattern C-G through a contact hole defined in the second insulating layer 20. In FIG. 6B, a region overlapping the first gate pattern C-P1 of the first active pattern A1-G, which will be described later, may be defined as an active region of the first transistor T1-G.

The third insulating layer 30 may be located on the second insulating layer 20, and may cover the first gate pattern C-P1. The third insulating layer 30 may be an organic layer.

The pixel-defining layer PDL and the first light-emitting element OLED-G of the first pixel PX-G may be located on the third insulating layer 30.

The opening PDL-OP may be defined in the pixel-defining layer PDL. The opening PDL-OP may expose at least a portion of a first electrode AE. The opening PDL-OP may be provided in plurality. The openings PDL-OP may one-to-one correspond to the first to third pixel regions PXA-R, PXA-G, and PXA-B described in FIG. 4.

According to one or more embodiments, the pixel-defining layer PDL may have light absorption properties, and for example, the pixel-defining layer PDL may be black in color. The pixel-defining layer PDL may include a black coloring agent. The black coloring agent may include a black dye and a black pigment. The black coloring agent may include carbon black, a metal, such as chromium, or an oxide thereof. The pixel-defining layer PDL may correspond to a light-blocking pattern having light-blocking properties.

The first electrode AE of the first light-emitting element OLED-G may be located on the third insulating layer 30. A second electrode CE may be located on the first electrode AE (as used herein, “on” may mean “above”). An emission layer EML may be located between the first electrode AE and the second electrode CE. The first light-emitting element OLED-G according to one or more embodiments may further include a hole control layer and an electron control layer. The hole control layer may be located between the first electrode AE and the emission layer EML. The electron control layer may be located between the emission layer EML and the second electrode CE. The hole control layer may include a hole transport layer and a hole injection layer. The electron control layer may include an electron transport layer and an electron injection layer. According to one or more embodiments, the hole control layer, the emission layer, the electron control layer, and the second electrode may be common layers commonly formed in the first to third pixels PX-G, PX-R, and PX-B.

The encapsulation layer TFE may cover the first light-emitting element OLED-G. The encapsulation layer TFE may include a first inorganic layer, an organic layer, and a second inorganic layer, which are sequentially stacked. The inorganic layers may include a silicon nitride layer, a silicon oxy nitride layer, a silicon oxide layer, a titanium oxide layer, or an aluminum oxide layer. The inorganic layers may each have a multilayer structure. The organic layer may include an acryl-based organic layer, but is not limited thereto. The inorganic layers may protect the first light-emitting element layer OLED-G from moisture and oxygen, and the organic layer may protect the first light-emitting element layer OLED-G from foreign substances, such as dust particles.

FIGS. 6A to 6G are plan views in which the stacking order of conductive patterns described in FIG. 5A is divided by layer.

Referring to FIGS. 5A, 5B, and 6A, a first conductive layer MSL1 may be located on the base layer BS and covered by the first insulating layer 10.

The first conductive layer MSL1 may include a second power line EL, first to third data lines DL-G, DL-R, and DL-B, first to third light-blocking patterns BML-G, BML-R, and BML-B, a power line EBR, and an initial line IL.

The second power line EL According to one or more embodiments of the present disclosure may extend in the second direction DR2. The second power line EL may be spaced apart from the second data line DL-R along the first direction DR1.

The first and second data lines DL-G and DL-R may each extend in the second direction DR2. The second data line DL-R may be located between the second power line EL and the first data line DL-G. The first data line DL-G may be spaced apart from the second power line EL in the first direction DR1 with the second data line DL-R therebetween.

The first and second light-blocking patterns BML-G and BML-R may be spaced apart along the second direction DR2. The first and second light-blocking patterns BML-G and BML-R may be located between the first data line DL-G and the power line EBR. The third light-blocking pattern BML-B may be located between the initial line IL and the third data line DL-B.

The first to third light-blocking patterns BML-G, BML-R, and BML-B may each correspond to lower electrodes of capacitors included in the corresponding pixel. The power line EBR may extend along the second direction DR2. The

power line EBR may be located between the first and second light-blocking patterns BML-G and BML-R and the initial line IL.

The initial line IL may extend along the second direction DR2. The initial line IL may be located between the power line EBR and the third light-blocking pattern BML-B.

The third light-blocking pattern BML-B may be located between the initial line IL and the third data line DL-B.

The third data line DL-B may extend in the second direction DR2. The third data line DL-B may be located between the third light-blocking pattern BML-B and the second power line located in the adjacent unit pixel PXU (see FIG. 4).

Referring to FIGS. 5A, 5B, and 6B, a second conductive layer MSL2 may be located on the first insulating layer 10, and may be covered by the second insulating layer 20.

The second conductive layer MSL2 may include first to third active patterns A1-G, A2-G, and A3-G and a first capacitor pattern C-G included in the first pixel PX-G, first to third active patterns A1-R, A2-R, and A3-R and second capacitor patterns C-R1 and C-R2 included in the second pixel PX-R, and first to third active patterns A1-B, A2-B, and A3-B and a third capacitor pattern C-B included in the third pixel PX-B.

The first capacitor pattern C-G (an upper electrode of the first capacitor Cst-G) may overlap the first blocking pattern BML-G to define the first capacitor Cst-G of the first pixel PX-G. The second capacitor patterns C-R1 and C-R2 (upper electrodes of the second capacitor Cst-R) may overlap the second light-blocking pattern BML-R to define the second capacitor Cst-R of the second pixel PX-R. The third capacitor pattern C-B (an upper electrode of the third capacitor Cst-B) may overlap the third light-blocking pattern BML-B to define the third capacitor Cst-B of the third pixel PX-B.

The first to third light-blocking patterns BML-G, BML-R, and BML-B may each correspond to lower electrodes of capacitors included in the corresponding pixel.

A portion of the first capacitor pattern C-G may be defined as the second active pattern A2-G, and a portion of a (2-2)-th capacitor pattern C-R2 may be defined as the second active pattern A2-R. The third capacitor pattern C-B may be spaced apart from the second active pattern A2-B along the second direction DR2 with the first active pattern A1-B therebetween.

A portion of each of the first capacitor pattern C-G and the first active pattern A1-G may overlap the first blocking pattern BML-G, and the second active pattern A2-G portion of the first capacitor pattern C-G might not overlap the first light-blocking pattern BML-G. The third active pattern A3-G may extend in the first direction DR1, and may be located between the first blocking pattern BML-G and the initial line IL when viewed on a plane.

A portion of each of a (2-1)-th capacitor pattern C-R1, the (2-2)-th capacitor pattern C-R2, and the first active pattern A1-R may overlap the second light-blocking pattern BML-R, and the second active pattern A2-R portion of the (2-2)-th capacitor pattern C-R2 might not overlap the second light-blocking pattern BML-R. The third active pattern A3-R may extend in the first direction DR1, and may be located between the second light-blocking pattern BML-R and the initial line IL when viewed on a plane.

A portion of each of the third capacitor pattern C-B, the first active pattern A1-B, and the second active pattern A2-B may overlap the third light-blocking pattern BML-B, and another portion of the second active pattern A2-B might not overlap the third light-blocking pattern BML-B. The third active pattern A3-B might not overlap the third blocking pattern BML-B, and may extend in the first direction DR1 to be located between the initial line IL and the third data line DL-B when viewed on a plane.

FIG. 6C shows contact holes CNT1 and CNT2 defined through at least one of the first and second insulating layers 10 and 20 described in FIG. 5B.

The first contact holes CNT1 may be defined through the first and second insulating layers 10 and 20. The first contact holes CNT1 may overlap conductive patterns included in the first conductive layer MSL1. Accordingly, conductive patterns located on different layers and overlapping the first contact holes CNT1 may be connected to each other through the first contact holes CNT1.

The second contact holes CNT2 may be defined through the second insulating layer 20. The second contact holes CNT2 may overlap conductive patterns included in the second conductive layer MSL2. Accordingly, conductive patterns located on different layers and overlapping the second contact holes CNT2 may be connected to each other through the second contact holes CNT2.

In FIG. 6C, for convenience of description, the first contact holes CNT1 are shown as relatively small squares, and the second contact holes CNT2 are shown as relatively large rectangles.

Referring to FIGS. 5A, 5B, and 6D, a third conductive layer MSL3 may be located on the second insulating layer 20 and covered by the third insulating layer 30.

The third conductive layer MSL3 may include a first power line ED, a sensing line SSL, a scan line SCL, first power patterns ED-P1 and ED-P2, second power patterns EL-P1 and EL-P2, data patterns D1-P, D2-P, and D3-P, electrode patterns A-P11, A-P12, A-P2, and A-P3, bridge patterns B-P1, B-P2, and B-P3, gate patterns C-P1, C-P2, and C-P3, and an initial patterns IL-P.

The first power line ED may extend along the first direction DR1. The first power line ED may be connected to the power line EBR through a first contact hole CNT1. The first voltage ELVDD described in FIG. 3 may be provided to the first power line ED.

The sensing line SSL may extend along the first direction DR1. According to one or more embodiments of the present disclosure, the sensing line SSL may be located below the first power line ED when viewed on a plane. A portion of the sensing line SSL may include a first pattern S-P protruding along the second direction DR2. A portion of the first pattern S-P, which overlaps the third active patterns A1-B and A2-B may be defined as a gate of the third transistor T3 (see FIG. 3).

The scan line SCL may extend along the first direction DR1. According to

one or more embodiments of the present disclosure, when viewed on a plane, the scan line SCL may be spaced apart from the sensing line SSL along the second direction DR2. Among the conductive patterns included in the third conductive layer MSL3, conductive patterns excluding the first power line ED may be located between the scan line SCL and the sensing line SSL when viewed on a plane.

A portion of the scan line SCL may include second patterns L-P1 and L-P2 protruding along the second direction DR2. A portion of a (2-1)-th pattern L-P1, which overlaps the second active patterns A2-G and A2-R, may be defined as a gate of the second transistor T2 (see FIG. 3). A portion of a (2-2)-th pattern L-P2, which overlaps the second active pattern A2-B, may be defined as a gate of the second transistor T2 (see FIG. 3).

According to one or more embodiments of the present disclosure, when viewed on a plane, the sensing line SSL including the first pattern S-P protruding downwardly is located below the scan line SCL including the (2-1)-th pattern L-P1 protruding upwardly, and accordingly, even when the first pixel PX-G is located on the left side of the first pattern S-P, an area of the first and second capacitors Cst-G and Cst-R may be secured.

The first power patterns ED-P1 and ED-P2 may overlap the power line EBR. The first power patterns ED-P1 and ED-P2 may be connected to the power line EBR through first contact holes CNT1. The first power patterns ED-P1 and ED-P2 may be spaced apart along the second direction DR2. A (1-1)-th power pattern ED-P1 may overlap a portion of the first active pattern A1-G. A portion of a (1-2)-th power pattern ED-P2 may protrude along the first direction DR1 and thus overlap the first active pattern A1-R, and another portion of the (1-2)-th power pattern ED-P2 may protrude along the first direction DR1 and thus overlap the first active pattern A1-B.

The second power patterns EL-P1 and EL-P2 may overlap the second power line EL. The second power patterns EL-P1 and EL-P2 may be connected to the second power line EL through first contact holes CNT1. The second voltage ELVSS described in FIG. 3 may be provided to the second power line EL. The second power patterns EL-P1 and EL-P2 may be spaced apart along the second direction DR2.

Among the data patterns D1-P, D2-P, and D3-P, a portion of the first data pattern D1-P may be connected to the first data line DL-G through a first contact hole CNT1, and another portion of the first data pattern D1-P may be connected to the second active pattern A2-G through a second contact hole CNT2.

A portion of the second data pattern D2-P may be connected to the second data line DL-R through a first contact hole CNT1, and another portion of the second data pattern D2-P may be connected to the second active pattern A2-R through a second contact hole CNT2.

A portion of the third data pattern D3-P may be connected to the third data line DL-B through a first contact hole CNT1, and another portion of the third data pattern D3-P may be connected to the second active pattern A2-B through a second contact hole CNT2.

Among the electrode patterns A-P11, A-P12, A-P2, and A-P3, a portion of a (1-1)-th electrode pattern A-P11 may be connected to the first light-blocking pattern BML-G through a first contact hole CNT1, and another portion of the (1-1)-th electrode pattern A-P11 may be connected to the third active pattern A3-G through a second contact hole CNT2. A portion of a (1-2)-th electrode pattern A-P12 may be connected to the first light-blocking pattern BML-G through a first contact hole CNT1. Another portion of the (1-2)-th electrode pattern A-P12 may be connected to the second electrode CE (see FIG. 5B) through a third contact hole CNT3 (see FIG. 6E) defined in the third insulating layer 30.

A portion of the second electrode pattern A-P2 may be connected to the second light-blocking pattern BML-R through a first contact hole CNT1, and another portion of the second electrode pattern A-P2 may be connected to the third active pattern A3-R through a second contact hole CNT2. The other portion of the second electrode pattern A-P2 may be connected to the second electrode CE (see FIG. 5B) through the third contact hole CNT3 (see FIG. 6E) defined in the third insulating layer 30.

A portion of the third electrode pattern A-P3 may be connected to the third light-blocking pattern BML-B through a first contact hole CNT1, and the other portion of the third electrode pattern A-P3 may be connected to the third active pattern A3-B through a second contact hole CNT2. The other portion of the second electrode pattern A-P2 may be connected to the second electrode CE (see FIG. 5B) through the third contact hole CNT3 (see FIG. 6E) defined in the third insulating layer 30.

Among the bridge patterns B-P1, B-P2, and B-P3, a portion of the first bridge pattern B-P1 may be connected to the first light-blocking pattern BML-G through a first contact hole CNT1, and another portion of the first bridge pattern B-P1 may be connected to the first active pattern A1-G through a second contact hole CNT2.

A portion of the second bridge pattern B-P2 may be connected to the second light-blocking pattern BML-R through a first contact hole CNT1, and another portion of the second bridge pattern B-P2 may be connected to the first active pattern A1-R through a second contact hole CNT2.

A portion of the third bridge pattern B-P3 may be connected to the third light-blocking pattern BML-B through a first contact hole CNT1, and another portion of the second bridge pattern B-P2 may be connected to the first active pattern A1-B through a second contact hole CNT2.

Among the gate patterns C-P1, C-P2, and C-P3, a portion of the first gate pattern C-P1 may be connected to the first capacitor pattern C-G through a second contact hole CNT2. When viewed on a plane, the first gate pattern C-P1 overlapping the first active pattern A1-G may be defined as a gate of the first transistor T1 (see FIG. 3).

A portion of the second gate pattern C-P2 may be connected to the (2-1)-th capacitor pattern C-R1 through a second contact hole CNT2. Another portion of the second gate pattern C-P2 may be connected to the (2-2)-th capacitor pattern C-R2 through a second contact hole CNT2. The second gate pattern C-P2 overlapping the first active pattern A1-R when viewed on a plane may be defined as a gate of the first transistor T1 (see FIG. 3).

A portion of the third gate pattern C-P3 may be connected to the third capacitor pattern C-B through a second contact hole CNT2. The third gate pattern C-P3 overlapping the first active pattern A1-B when viewed on a plane may be defined as a gate of the first transistor T1 (see FIG. 3).

The initial pattern IL-P may overlap the initial line IL when viewed on a plane, and may be connected to the initial line IL through first contact holes CNT1. The initial voltage Vintit (see FIG. 3) may be provided to the initial line IL.

A portion of the initial pattern IL-P may be connected to the second active patterns A2-G and A2-R through second contact holes CNT2, and another portion of the initial pattern IL-P may be connected to the second active pattern A2-B through a second contact hole CNT2.

FIG. 6E shows third contact holes CNT3 defined through the third insulating layer 30 described in FIG. 5B. The third contact holes CNT3 may overlap any one of the conductive patterns included in the third conductive layer MSL3. For example, the third contact holes CNT3 may overlap the (2-1)-th power pattern EL-P1, the (1-2)-th electrode pattern A-P12, and the second and third electrode patterns A-P2 and A-P3.

Referring to FIGS. 5A, 5B, and 6F, a fourth conductive layer MSL4 may be located on the third insulating layer 30, and may be covered by the pixel-defining layer PDL.

The fourth conductive layer MSL4 may include a power pattern EL-P and first to third first electrodes AE-G, AE-R, and AE-B. The first to third first electrodes AE-G, AE-R, and AE-B may correspond to the first electrode AE described in FIG. 5A.

The power pattern EL-P may be provided with the second voltage ELVSS (see FIG. 3) through the second power line EL and the (2-1)-th power pattern EL-P1. The power pattern EL-P may be connected to the second electrode CE described in FIG. 5A.

The first electrode AE-G of the first pixel PX-G may be connected to the (1-2)-th electrode patterns A-P12 through the third contact hole CNT3. The first electrode AE-R of the second pixel PX-R may be connected to the second electrode pattern A-P2 through the third contact hole CNT3. The first electrode AE-B of the third pixel PX-B may be connected to the third electrode pattern A-P3 through the third contact hole CNT3.

According to one or more embodiments of the present disclosure, even when the first electrode AE-G of the first pixel PX-G is biased to the left side when viewed on the plane, the first electrode AE-G might not overlap the second capacitor Cst-R of the second pixel PX-R. The first capacitor Cst-G of the first pixel PX-G may only overlap the first electrode AE-G of the first pixel PX-G, and the second capacitor Cst-R of the second pixel PX-R may only overlap the first electrode AE-G of the first pixel PX-G. In addition, when viewed in the first direction DR1, the second capacitor Cst-R of the second pixel PX-R might not overlap the first electrode AE-G and the first electrode AE-G of the first pixel PX-G.

According to one or more embodiments of the present disclosure, an area in which the second capacitor Cst-R of the second pixel PX-R is located may be secured. Accordingly, a display panel DP having improved driving properties of pixels may be provided.

Referring to FIGS. 5A, 5B, and 6G, the pixel-defining layer PDL may be located on the fourth conductive layer MSL4. First to third openings PXA-G, PXA-R, and PXA-B and a power opening OP-E may be defined in the pixel-defining layer PDL. The first to third openings PXA-R, PXA-G, and PXA-B may correspond to the first to third pixel regions PXA-R, PXA-G, and PXA-B described in FIG. 4.

The first opening PXA-G may overlap the first electrode AE-G, and thus may expose at least a portion of the first electrode AE-G. The second opening PXA-R may overlap the first electrode AE-R, and thus expose at least a portion of the first electrode AE-R. The third opening PXA-B may overlap the first electrode AE-B, and thus expose at least a portion of the first electrode AE-B.

According to one or more embodiments, an area of the second opening PXA-R may be less than an area of the first opening PXA-G and may be greater than an area of the third opening PXA-B. The second opening PXA-R and the third opening PXA-B may be located in the same row, and the first opening PXA-G may be located in a different row from the second opening PXA-R and the third opening PXA-B. For example, the second opening PXA-R and the third opening PXA-B may be arranged to be spaced apart along the first direction DR1, and the first opening PXA-G may be arranged to be spaced apart from the second opening PXA-R and the third opening PXA-B in a diagonal direction with respect to each of the first direction DR1 and the second direction DR2.

According to one or more embodiments of the present disclosure, electrodes included in a capacitor may be located in a wide region by optimizing the arrangement order of patterns included in a conductive layer. Accordingly, the function of the capacitor is improved, and thus a display panel including pixels with increased driving characteristics may be provided.

Although the present disclosure has been described with reference to various embodiments, it will be understood that the present disclosure should not be limited to these embodiments but various changes and modifications may be made by those skilled in the art without departing from the spirit and scope of the present disclosure. Hence, the present disclosure is not limited to the detailed descriptions in the specification, but should be determined only with reference to the claims, with functional equivalents thereof to be included therein.

What is claimed is:

1. A display panel comprising:
a base layer;
unit pixels comprising first, second, and third pixels above the base layer, arranged along a first direction and a second direction, which cross each other, and comprising first, second, and third transistors above the base layer, a capacitor, and a light-emitting element;
a first power line extending along the first direction;
a sensing line extending along the first direction, and spaced apart from the first power line along the second direction;
a scan line extending along the first direction and spaced apart from the first power line along the second direction with the sensing line therebetween; and
first, second, and third data lines spaced apart along the first direction, extending along the second direction, and respectively connected to the first, second, and third pixels,
wherein the capacitor of the first pixel is spaced apart from the capacitor of the second pixel along the second direction, and
wherein the capacitor of the first pixel and the capacitor of the second pixel are spaced apart from the capacitor of the third pixel along the first direction.

2. The display panel of claim 1, wherein the capacitors are between the sensing line and the scan line,
wherein the sensing line overlaps an upper portion of the capacitors, and
wherein the scan line overlaps a lower portion of the capacitors.

3. The display panel of claim 1, wherein the first data line is between the second data line and the third data line, and
wherein the capacitors are between the first data line and the third data line.

4. The display panel of claim 1, wherein the capacitors respectively comprise upper electrodes, and respectively comprise first, second, and third light-blocking patterns above the base layer as respective lower electrodes.

5. The display panel of claim 4, further comprising a first capacitor pattern overlapping the first light-blocking pattern, a second capacitor pattern overlapping the second light-blocking pattern, and a third capacitor pattern overlapping the third light-blocking pattern respectively as the upper electrodes.

6. The display panel of claim 5, wherein a portion of the first capacitor pattern not overlapping the first light-blocking pattern comprises an active pattern of the second transistor of the first pixel,
wherein a portion of the second capacitor pattern not overlapping the second light-blocking pattern comprises an active pattern of the second transistor of the second pixel, and
wherein a portion of the third capacitor pattern not overlapping the third light-blocking pattern comprises an active pattern of the second transistor of the third pixel.

7. The display panel of claim 6, wherein the scan line comprises a first pattern and a second pattern protruding along the second direction and spaced apart along the first direction, the first pattern overlapping the active pattern of the second transistor of the first pixel and the second transistor of the second pixel, and the second pattern overlapping the active pattern of the second transistor of the third pixel.

8. The display panel of claim 7, wherein portions of the first pattern and the second pattern overlapping the active patterns comprise gates of the second transistors of the first, second, and third pixels.

9. The display panel of claim 7, wherein the second capacitor pattern comprises a (2-1)-th capacitor pattern and a (2-2)-th capacitor pattern spaced apart along the second direction, and
wherein the active pattern of the first transistor of the second pixel is between the (2-1)-th capacitor pattern and the (2-2)-th capacitor pattern.

10. The display panel of claim 9, further comprising a gate pattern comprising a gate of the first transistor of the second pixel overlapping the active pattern of the first transistor of the second pixel, the gate pattern connecting the (2-1)-th capacitor pattern and the (2-2)-th capacitor pattern.

11. The display panel of claim 5, further comprising:
a first insulating layer above the base layer, and covering the first, second, and third data lines and the first, second, and third light-blocking patterns;
a second insulating layer above the first insulating layer, and covering the first, second, and third capacitor patterns;
a third insulating layer above the second insulating layer, and covering the first power line, the sensing line, and the scan line; and
a pixel-defining layer above the third insulating layer, and defining openings exposing at least a portion of first electrodes of the light-emitting elements.

12. The display panel of claim 11, wherein, among the openings, an opening corresponding to the first electrode of the first pixel is defined as a first pixel region, an opening corresponding to the first electrode of the second pixel is defined as a second pixel region, and an opening corresponding to the first electrode of the third pixel is defined as a third pixel region, and
wherein an area of the second pixel region is less than an area of the first pixel region, and is greater than an area of the third pixel region.

13. The display panel of claim 12, wherein the second pixel region and the third pixel region are spaced apart along the first direction, and
wherein the first pixel region is spaced apart from the second pixel region and the third pixel region in respective diagonal directions that are diagonal with respect to the first direction and the second direction.

14. The display panel of claim 11, further comprising a second power line connected to a second electrode of the first, second, and third pixels, above the base layer, extending along the second direction, and spaced apart from the second data line along the first direction.

15. A display panel comprising:
a base layer;
first, second, and third pixels above the base layer and comprising first, second, and third transistors, a capacitor, and a light-emitting element;
first, second, and third data lines spaced apart along a first direction, and extending along a second direction crossing the first direction;
a first power line extending along the first direction;
a sensing line extending along the first direction;
a scan line extending along the first direction;
a second power line extending along the second direction; and
an initial line extending along the second direction,
wherein the second power line, the second data line, the first data line, the capacitor of the first pixel, the capacitor of the second pixel, the initial line, the capacitor of the third pixel, and the third data line are sequentially arranged along the first direction.

16. The display panel of claim 15, wherein the first power line is spaced apart from the scan line along the second direction with the sensing line therebetween, and
wherein the capacitors of the first, second, and third pixels are between the sensing line and the scan line.

17. The display panel of claim 16, wherein the capacitor of the first pixel is spaced apart from the capacitor of the second pixel along the second direction, and
wherein the capacitor of the first pixel and the capacitor of the second pixel are spaced apart from the capacitor of the third pixel along the first direction.

18. The display panel of claim 17, wherein the initial line is between the capacitor of the third pixel and the capacitors of the first pixel and the second pixel.

19. The display panel of claim 15, further comprising:
a first insulating layer above the base layer and covering the first, second, and third data lines, the second power line, and the initial line;
a second insulating layer above the first insulating layer, and covering active patterns of the first, second, and third transistors;
a third insulating layer above the second insulating layer, and covering the first power line, the sensing line, and the scan line; and
a pixel-defining layer above the third insulating layer, and defining openings exposing at least a portion of first electrodes of the light-emitting elements defined therein.

20. The display panel of claim 19, wherein the capacitors comprise a lower electrode above the base layer and covered by the first insulating layer, and an upper electrode above the first insulating layer and covered by the second insulating layer.
